(19) United States
(12) Patent Application Publication
(10) Pub. No.: US 2014/0253241 A1
(43) Pub. Date: Sep. 11, 2014

(54) HIGH ELECTRON MOBILITY TRANSISTOR DEVICE

(71) Applicant: Samsung Electronics Co., Ltd., Suwon-si (KR)

(72) Inventors: Jae-Hoon Lee, Suwon-si (KR); Chan-ho Park, Seongnam-si (KR); Nam-young Lee, Hwaseong-si (KR)

(73) Assignee: Samsung Electronics Co., Ltd., Suwon-si (KR)

(21) Appl. No.: 14/077,678

(22) Filed: Nov. 12, 2013

(30) Foreign Application Priority Data
Mar. 8, 2013 (KR) 1020130025250

(51) Int. Cl. H01L 29/778; H03F 3/193; H01L 29/20

(52) U.S. Cl. CPC H01L 29/778; H01L 29/2003; H03F 3/193
USPC 330/277; 257/76; 257/194

(57) ABSTRACT

A high electron mobility transistor (HEMT) device includes a buffer layer on a substrate; a face-inversion layer on a part of the buffer layer; a plurality of semiconductor layers on the face-inversion layer and on the buffer layer; and a source electrode, a drain electrode, and a gate electrode on the plurality of semiconductor layers. The HMT device has a stable, normally Off characteristic.

### CROSS-REFERENCE TO RELATED APPLICATIONS

This application claims priority under 35 U.S.C. §119 from Korean Patent Application No. 10-2013-0025250, filed on Mar. 8, 2013, in the Korean Intellectual Property Office, the disclosure of which is incorporated herein in its entirety by reference.

### BACKGROUND

The inventive concepts relate to a high electron mobility transistor (HEMT) device, and more particularly, to a HEMT device that has a normally “Off” characteristic.

In order to use a transistor for a power device that achieves a high breakdown voltage and a fast response speed, research into high electron mobility transistors (HEMT) has been actively conducted. The HEMT device includes semiconductor layers with different electrical polarization characteristics; and some semiconductor layers with relatively large degrees of polarizability in the HEMT device may cause other semiconductor layers bonded heterogeneously thereto to generate a two-dimensional electron gas (2DEG), i.e., a gas of electrons free to move in two dimensions, but tightly confined in the third dimension. The 2DEG may serve as a channel between a drain electrode and a source electrode, and currents flowing in the channel may be controlled by a bias voltage applied to a gate electrode. A conventional HEMT device, e.g., a HEMT device using heterogeneous bonding by a group III-nitride semiconductor, has a normally “On” characteristic and high power consumption due to such a normally On characteristic.

### SUMMARY

The inventive concepts provide a high electron mobility transistor with a stable, normally Off characteristic.

According to an aspect of the inventive concepts, there is provided a high electron mobility transistor (HEMT) device including a buffer layer on a substrate; a face-inversion layer on a part of the buffer layer; a plurality of semiconductor layers on the face-inversion layer and the buffer layer; and a source electrode, a drain electrode, and a gate electrode on the plurality of semiconductor layers.

A polarity of the buffer layer may be different from polarities of the plurality of semiconductor layers that are arranged on the face-inversion layer.

A channel region may be formed in the plurality of semiconductor layers; a two-dimensional electron gas (2DEG) layer may be formed in the channel region; and the 2DEG region may not be formed on a part of the channel region that overlaps with the gate electrode.

The face-inversion layer may be disposed to overlap with the gate electrode.

The buffer layer may have a Ga-face polarity; parts of the plurality of semiconductor layers on the buffer layer may also have a Ga-face polarity; and parts of the plurality of semiconductor layers on the face-inversion layer may have an N-face polarity.

The plurality of semiconductor layers may include a first semiconductor layer on the buffer layer and the face-inversion layer, wherein the first semiconductor layer includes gallium nitride GaN, and a second semiconductor layer on the first semiconductor layer, wherein the second semiconductor layer includes aluminum gallium nitride (AlₓGa₁₋ₓN), where 0<x<1, and wherein a channel region may be formed in the first semiconductor layer.

The buffer layer may have an N-face polarity; parts of the plurality of semiconductor layers on the buffer layer may also have an N-face polarity; and parts of the plurality of semiconductor layers on the face-inversion layer may have a Ga-face polarity.

The plurality of semiconductor layers may include a first semiconductor layer on the buffer layer and on the face-inversion layer, wherein the first semiconductor layer includes gallium nitride (GaN); a second semiconductor layer on the first semiconductor, wherein the second semiconductor layer includes aluminum gallium nitride AlₓGa₁₋ₓN, where 0<x<1; and a third semiconductor layer on the second semiconductor layer, wherein the third semiconductor layer includes gallium nitride (GaN), and wherein a channel region may be formed in the first semiconductor layer.

The face-inversion layer may be disposed to not overlap with the gate electrode.

The face-inversion layer may be formed to overlap with the source electrode and the drain electrode.

The face-inversion layer may include magnesium-doped gallium nitride, aluminum nitride doped with p-type impurities, magnesium carbide (MgC), or magnesium carbon nitride (MgCN).

The HEMT device may further include a high-resistance semiconductor layer under the plurality of semiconductors.

According to another aspect of the inventive concept, there is provided a high electron mobility transistor (HEMT) including a buffer layer on a substrate; a face-inversion layer on a part of the buffer layer; a high-resistance semiconductor layer on the buffer layer and on the face-inversion layer; a channel layer and a channel-supplying layer sequentially formed on the high-resistance semiconductor layer; a source electrode and a drain electrode connected to the channel layer; and a gate electrode on the channel-supplying layer; and wherein a polarity of a part of the buffer layer under the face-inversion layer is different from a polarity of a part of the high-resistance semiconductor layer on the face-inversion layer.

A bottom of the gate electrode may be on a level higher than that of a top of the channel-supplying layer.

A part of the channel-supplying layer under the gate electrode may have a flat shape.

According to another aspect of the inventive concept, a radio frequency power amplifier module includes a power amplifier module, a transceiver, and an antenna switch module.

The power amplifier module includes at least one high electron mobility transistor (HEMT), including a substrate; a buffer layer on the substrate; a face-inversion layer on a part of the buffer layer; a plurality of semiconductor layers on the face-inversion layer and on the buffer layer; and a source electrode, a drain electrode, and a gate electrode on the plurality of semiconductor layers.

The transceiver is coupled with the power amplifier module and is configured to receive an input signal and to transmit the input signal to the power amplifier module; and the power amplifier module is configured to amplify the input signal received from the transceiver.

The antenna switch module is coupled with the power amplifier module and includes an antenna structure, wherein the antenna switch module is configured to receive the amplified input signal from the power amplifier module and to transmit the amplified input signal over the air via the antenna structure.

The antenna switch module may also be configured to receive the input signal through the antenna structure and to transmit the input signal to the transceiver.

A polarity of the buffer layer may be different from polarities of the plurality of semiconductor layers that are arranged on the face-inversion layer.

The radio frequency power amplifier module may further include a channel region formed in the plurality of semiconductor layers and a two-dimensional electron gas (2DEG) region formed in the channel region, wherein the 2DEG region is not formed on a part of the channel region that overlaps with the gate electrode.

The face-inversion layer may be disposed to overlap either (a) with the gate electrode but not with the source electrode and not with the drain electrode or (b) with the source electrode and with the drain electrode but not with the gate electrode.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a high electron mobility transistor (HEMT) device according to an exemplary embodiment;

FIG. 2 represents (A) a crystal structure of a GaN layer with an N-face polarity and (B) a crystal structure of a GaN layer with a Ga-face polarity;

FIG. 3 represents (A) a polarization direction of a hetero-structure with an N-face polarity and (B) a polarization direction of a hetero-structure with a Ga-face polarity;

FIG. 4 is a cross-sectional view of an HEMT device according to an exemplary embodiment of the present inventive concepts;

FIG. 5 is a cross-sectional view of an HEMT device according to an exemplary embodiment of the present inventive concepts;

FIG. 6 is a cross-sectional view of an HEMT device according to an exemplary embodiment of the present inventive concepts;

FIGS. 7A to 7E are cross-sectional views related to a method of fabricating an HEMT device according to an exemplary embodiment of the present inventive concepts; and

FIG. 8 is a schematic block diagram of a power module system employing an HEMT device according to an exemplary embodiment.

### DETAILED DESCRIPTION OF THE EMBODIMENTS

Exemplary embodiments of the present inventive concepts will be described in detail with reference to the accompanying drawings. As used herein, the term, “and/or,” includes any and all combinations of one or more of the associated listed items. Expressions such as, “at least one of,” when preceding a list of elements, modify the entire list of elements and do not modify the individual elements of the list.

The inventive concepts may, however, be embodied in many different forms and should not be construed as being limited to the embodiments set forth herein; rather, these embodiments are provided so that this disclosure will be thorough and complete, and will fully convey the concepts of the invention to those of ordinary skill in the art. In the drawings, the thickness or size of each layer is exaggerated for convenience of description and clarity.

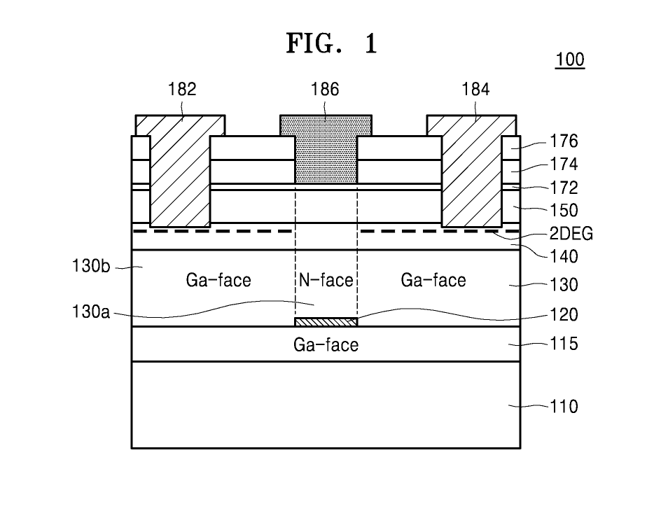

FIG. 1 is a cross-sectional view of a high electron mobility transistor (HEMT) device according to an exemplary embodiment.

Referring to FIG. 1, an HEMT device 100 may include a substrate 110, a buffer layer 115, a face-inversion layer 120, a high-resistance semiconductor layer 130, a channel layer 140, a channel-supplying layer 150, a source electrode 182, a drain electrode 184, and a gate electrode 186.

The substrate 110 may be a sapphire substrate, a silicon carbide substrate, a gallium nitride substrate, a silicon substrate, a germanium substrate, an aluminum nitride substrate, etc. For example, a single crystal silicon carbide substrate with high thermal conductivity may be used as the substrate 110.

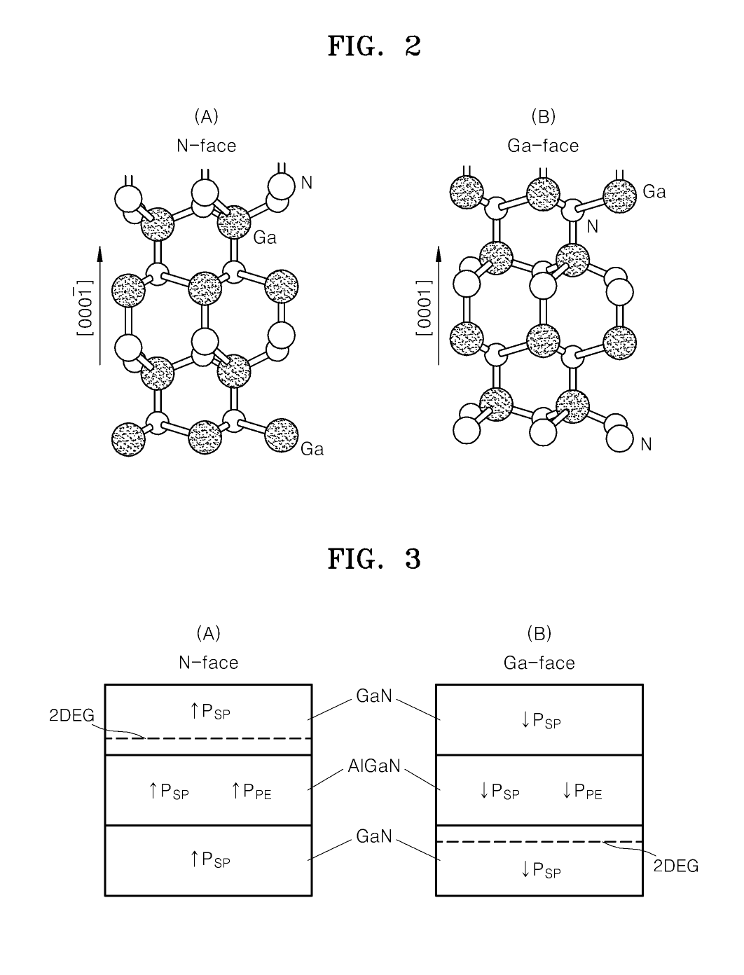

The buffer layer 115 may be formed on the substrate 110. The buffer layer 115 may work as a stress alleviating region that alleviates stress generated due to a lattice constant difference between the substrate 110 and the high-resistance semiconductor layer 130 or defects, such as misfit dislocations generated due to the lattice constant difference. In exemplary embodiments, the buffer layer 115 may include gallium nitride, aluminum nitride, aluminum gallium nitride, silicon carbon nitride, or combinations thereof. The buffer layer 115 may be formed to have a Ga-face polarity. The Ga-face polarity will be described with reference to FIGS. 2 and 3.

Although not shown, a superlattice layer (not shown), which has a multi-layer structure of aluminum nitride/gallium nitride/aluminum nitride/gallium nitride, may be further formed between the substrate 110 and the buffer layer 115. In addition, a stacked structure of a plurality of aluminum gallium nitride AlₓGa₁₋ₓN layers with different contents forms may be further included. In addition, a plurality of protrusions (not shown) may be further formed between the substrate 110 and the buffer layer 115.

The face-inversion layer 120 may be formed on a region of the buffer layer 115. The face-inversion layer 120 may be arranged to face a region of the gate electrode 186. In other words, the face-inversion layer 120 may be arranged to vertically overlap with the gate electrode 186, which is formed on the face-inversion layer 120. In exemplary embodiments, the face-inversion layer 120 may include at least one of the following compositions: magnesium-doped gallium nitride, p-type aluminium nitride, magnesium carbide, magnesium carbon nitride, etc. In addition, the face-inversion layer 120 may include at least one of the following compositions: gallium nitride doped with magnesium, aluminium, carbon, zinc, or indium, etc.

The high-resistance semiconductor layer 130 that covers the face-inversion layer 120 may be formed on the buffer layer 115. In exemplary embodiments, the high-resistance semiconductor layer 130 may include a material having a high sheet resistance. In this case, when electrons move in the channel layer 140 on the high-resistance semiconductor layer 130, leakage of currents through the high-resistance semiconductor layer 130 may be avoided. Thus, electron mobility in the channel layer 140 may be increased, thereby decreasing “on”-resistance of the HEMT device 100. In this case, the on-resistance indicates a resistance between the source electrode 182 and the drain electrode 184 while a voltage is applied to the gate electrode 186. For example, the high-resistance semiconductor layer 130 may include a gallium nitride layer having a sheet resistance of about 10⁷ Ωcm⁻² to 10¹¹ Ωcm⁻², but the high-resistance semiconductor layer 130 is not limited thereto. In exemplary embodiments, the high-resistance semiconductor layer 130 may be a non-doped gallium nitride layer or a doped gallium nitride layer in which dopants, such as magnesium (Mg), zinc (Zn), carbon (C), or iron (Fe), etc., are doped.

The high-resistance semiconductor layer 130 may be divided into a first region 130a that is formed on the face-inversion layer 120, and a second region 130b that is in contact with the buffer layer 115. The second region 130b of the high-resistance semiconductor layer 130 on the buffer layer 115 may have a Ga-face polarity, which may be the same as the Ga-face polarity of the buffer layer 115. This is because the second region 130b of the high-resistance semiconductor layer 130, which is epitaxially-grown using the buffer layer 115 as a seed layer, has the same crystal direction as that of the buffer layer 115. The first region 130a of the high-resistance semiconductor layer 130 on the face-inversion 120 may have an N-face polarity and may be opposite to the Ga-face polarity of the buffer layer 115. This is due to the face-inversion layer 120 formed at an interface between the buffer layer 115 serving as the seed layer and the high-resistance semiconductor layer 130. For example, when the face-inversion layer 120 is a gallium nitride layer including magnesium, it may be stable in terms of energy such that a magnesium-terminated [000 1̅] gallium nitride face is arranged on a magnesium-terminated [0001] gallium nitride face. In this case, the high-resistance semiconductor layer 130 epitaxially-grown on the face-inversion layer 120 may have an N-face polarity.

The channel layer 140 may be formed on the high-resistance semiconductor layer 130. The channel layer 140 may include at least one of various materials including aluminum nitride, gallium nitride, indium nitride, indium gallium nitride, aluminum gallium nitride, aluminum indium nitride, etc. However, the material of the channel layer 140 is not limited thereto and any material layer in which a two-dimensional electron gas (2DEG) may be formed may be used. The channel layer 140 may be an undoped semiconductor layer, but in some cases, the channel layer 140 may be a semiconductor layer in which a given dopant is doped. For example, the channel layer 140 may be an undoped gallium nitride layer. For example, the thickness of the channel layer 140 may be in a range of about 10 nm to about 100 nm.

The channel-supplying layer 150 may be formed on the channel layer 140. The channel-supplying layer 150 may include a semiconductor material having a band gap energy (E_{g}) higher than that of the channel layer 140. In exemplary embodiments, the channel-supplying layer 150 may have a single layered or multi-layered structure including one or more materials that are selected from nitrides including at least one of aluminum, gallium, and indium. In exemplary embodiments, the channel-supplying layer 150 may be an undoped aluminum gallium nitride layer. For example, the channel-supplying layer 150 may be a AlₓGa₁₋ₓN layer, where 0<x<1, or a AlₓGa₁₋ₓN layer, where 0.15≦x≦0.6. The channel-supplying layer 150 may have a thickness of about 20 nm to about 50 nm.

A 2DEG region may be formed in a part of the channel layer 140 near an interface between the channel layer 140 and the channel-supplying layer 150. When there is a hetero-structure in which the channel layer 140 and the channel-supplying layer 150 are gallium nitride and aluminum gallium nitride, respectively, the 2DEG region may be formed at III-V nitride layers (that is, the gallium nitride layer and the aluminum gallium nitride layer) by spontaneous polarization (SP) and piezo polarization (PE) due to tensile strain. The 2DEG region may function as a current passage between the source electrode 182 and the drain electrode 184, i.e., as a channel region. However, in a case where the 2DEG region is formed throughout an interface between the channel layer 140 and the channel-supplying layer 150, a normally On characteristic may be exhibited, which indicates that currents flow between the source electrode 182 and the drain electrode 184 even while a voltage is not applied to the gate electrode 186. According to an embodiment of the present inventive concepts, the surface polarity of the channel layer 140 may be selectively controlled using the fact that the location of the 2DEG region varies depending on the polarity of the III-V nitride layer. Thus, the 2DEG region may not be partially formed under the gate electrode 186, and the HEMT device 100 may have the normally Off characteristic.

Selectively, a capping layer (not shown) may be further formed on the channel-supplying layer 150. The capping layer may be an n-type semiconductor layer and include, e.g., silicon-doped aluminum gallium nitride. The capping layer and the channel-supplying layer 150 may form a p-n junction, thereby preventing currents from leaking from the gate electrode 186.

A gate insulation layer 172, a first passivation layer 174, and a second passivation layer 176 may be sequentially formed on the channel-supplying layer 150. In exemplary embodiments, the gate insulation layer 172 may include a dielectric material, such as any of the following: silicon oxide, silicon nitride, aluminium oxide, tantalum oxide, hafnium oxide, etc. In addition, the first passivation layer 174 and the second passivation layer 176 may include any of the following: silicon oxide, silicon nitride, silicon oxynitride, etc. The first passivation layer 174 may include material that is the same as or different from that of the second passivation layer 176.

Each of the source electrode 182 and the drain electrode 184 may be connected to the channel layer 140 through the channel-supplying layer 150, the gate insulation layer 172, and the passivation layers 174 and 176. In exemplary embodiments, the source and drain electrodes 182 and 184 may have a stacked structure in which a plurality of metal layers are stacked and may form an ohmic contact with the channel layer 140. For example, the source and drain electrodes 182 and 184 may include at least one of tantalum (Ta), tantalum nitride (TaN), tungsten (W), aluminum (Al), titanium (Ti), and titanium nitride (TiN). For example, the source electrode 182 and the drain electrode 184 may have a stacked structure in which layers including tantalum (Ta), aluminum (Al), tungsten (W), and titanium nitride (TiN) are stacked.

The gate electrode 186 may be formed on the channel-supplying layer 150 between the source electrode 182 and the drain electrode 184, and the gate electrode 186 may pass through the first passivation layer 174 and the second passivation layer 176. The gate electrode 186 may control currents that flow between the source electrode 182 and the drain electrode 184. The gate insulation layer 172 may be interposed between a bottom surface of the gate electrode 186 and a top surface of the channel-supplying layer 150. The channel-supplying layer 150 facing the gate electrode 186 may be formed in a flat shape, and the channel-supplying layer 150 under the gate electrode 186 may be formed to have a uniform thickness. In addition, the bottom surface of the gate electrode 186 may be on a level higher than that of the top surface of the channel-supplying layer 150.

Although FIG. 1 shows that the source electrode 182, the drain electrode 184, and the gate electrode 186 pass through the first passivation layer 174 and the second passivation layer 176, the first passivation layer 174 and the second passivation layer 176 may not be formed. In such a case, the source electrode 182 and the drain electrode 184 may pass through the gate insulation layer 172 and the channel-supplying layer 150 and be connected to the channel layer 140, and the gate electrode 186 may be formed on the gate insulation layer 172.

The N-face polarity and the Ga-face polarity are described, below, with reference to FIG. 2. FIG. 2 shows (A) a crystal structure of a GaN layer with an N-face polarity and (B) a crystal structure of a GaN layer with a Ga-face polarity.

Referring to FIG. 2, the GaN layer of a wurtzite structure may have an N-face polarity in which N atoms are arranged on the top layer (exposed surface) as in (A) or may have a Ga-face polarity in which Ga atoms are arranged on the top layer (exposed surface) as in (B). The N-face polarity may be implemented by growing Ga atoms earlier than N atoms and the Ga-face polarity may be implemented by growing N atoms earlier than Ga atoms. The N-face GaN layer of (A) may have a [000 1̅] direction in a z-axis direction, and the Ga-face GaN layer of (B) may have a [0001] direction in the z-axis direction.

In a GaN-based hetero-structure, e.g., a GaN/AlGaN structure, the location of the 2DEG region may vary depending on the face polarities of GaN and AlGaN. Referring to (A) of FIG. 3, when a stacked structure of GaN/AlGaN/GaN layers has an N-face polarity, spontaneous polarization (SP) and piezo polarization (PE) may be formed at an upper part; and, thus, the 2DEG region may be formed in an upper GaN layer over the AlGaN layer. Referring to (B) of FIG. 3, when a stacked structure of GaN/AlGaN/GaN layers has a Ga-face polarity, the spontaneous polarization (SP) and the piezo polarization (PE) may be formed at a lower part; and, thus, the 2DEG region may be formed in a lower GaN layer under the AlGaN layer. As such, the location of the 2DEG region may vary depending on the face polarity of a hetero-structured GaN-based semiconductor layer.

Referring back to FIG. 1, the second region 130b of the high-resistance semiconductor layer 130 of the HEMT device 100 may have a Ga-face polarity, and parts of the channel layer 140 and the channel-supplying layer 150 over the second region 130b may also have a Ga-face polarity. In addition, the first region 130a of the high-resistance semiconductor layer 130 may have an N-face polarity, and parts of the channel layer 140 and the channel-supplying layer 150 over the first region 130a may also have an N-face polarity. Since the first region 130a vertically overlaps with the gate electrode 186, the parts of the channel layer 140 and the channel-supplying layer 150 having the N-face polarity may vertically overlap with the gate electrode 186.

A 2DEG region may be formed in the parts of the channel layer 140 having the Ga-face polarity (i.e., in a part of the channel layer 140 between the source electrode 182 and the gate electrode 186 and in a part of the channel layer 140 between the drain electrode 184 and the gate electrode 186) due to the channel-supplying layer 150 (i.e., AlGaN layer) that is disposed thereon. On the other hand, a 2DEG region may not be formed in the part of the channel layer 140 having an N-face polarity (i.e., in a part of the channel layer 140 under the gate electrode 186). As discussed above, in the stacked structure having the N-face polarity, the 2DEG region may be formed in the upper GaN layer, and thus the 2DEG region may not be formed in the parts of the channel layer 140 under the channel-supplying layer 150. Thus, the 2DEG region may be discontinuous at the channel layer 140 under the gate electrode 186, it is possible to prevent currents from flowing through the 2DEG region in the channel layer 140 while a voltage is not applied to the gate electrode 186.

According to embodiments of the present inventive concepts, the HEMT device 100 may include the face-inversion layer 120 on a part of the buffer layer 115 that faces the gate electrode 186. Thus, the part of the channel layer 140 and the part of the channel-supplying layer 150 between the gate electrode 186 and the face-inversion layer 120 may be formed as face-inversed regions. This indicates that the part of the channel layer 140 and the part of the channel-supplying layer 150 on the face-inversion layer 120 include a material having a polarity different from those of a part of the channel layer 140 and a part of the channel-supplying layer 150 under which the face-inversion layer 120 is not formed. The 2DEG region may not be partially formed in the channel layer 140 of the face-inversed region, and thus, the HEMT device 100 may exhibit stable, normally Off characteristics.

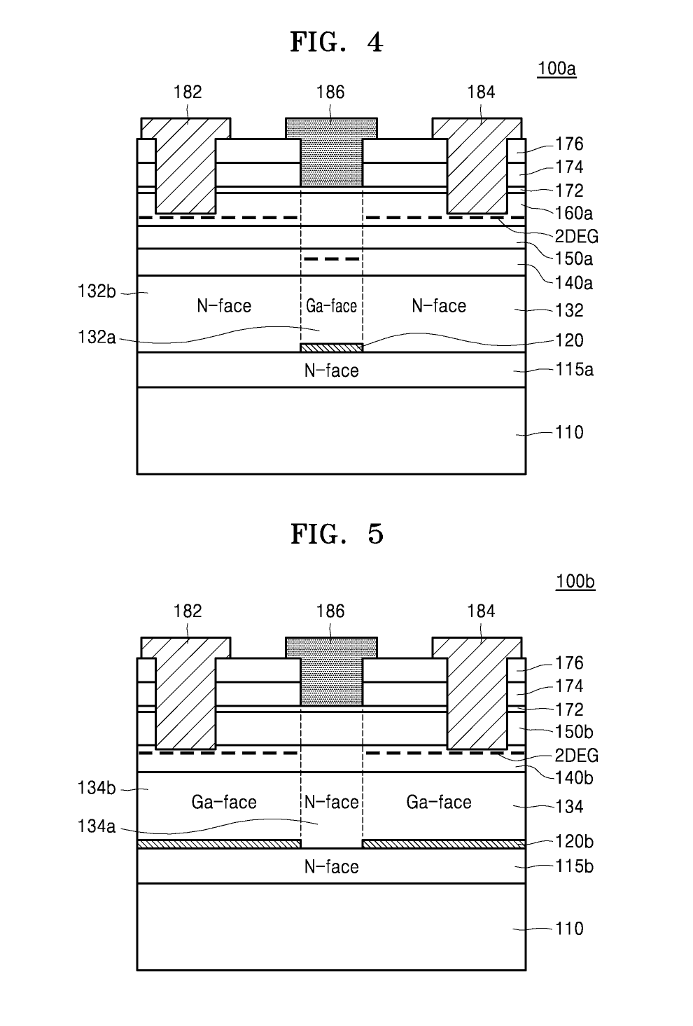

FIG. 4 is a cross-sectional view of an HEMT device 100a according to an exemplary embodiment of the present inventive concepts. The HEMT device 100a is similar to the HEMT device described with reference to FIG. 1, except that a channel layer is further formed over the channel-supplying layer.

Referring to FIG. 4, a buffer layer 115a may be formed on the substrate 110 and the face-inversion layer 120 may be formed on a region of the buffer layer 115a. In exemplary embodiments, the buffer layer 115a may be a nitride semiconductor layer with an N-face polarity.

A high-resistance semiconductor layer 132 may be formed on the substrate and on the buffer layer 115a. A part of the high-resistance semiconductor layer 132 that is formed on the face-inversion layer 120 may be referred to as a first region 132a, and a part of the high-resistance semiconductor layer 132 under which the face-inversion layer is not formed may be referred to as a second region 132b. The second region 132b may have an N-face polarity that is the same polarity as that of the buffer layer 115a, and the first region 132a may have a Ga-face polarity.

A lower channel layer 140a, a channel-supplying layer 150a, and an upper channel layer 160a may be sequentially formed on the high-resistance semiconductor layer 132. In exemplary embodiments, the lower channel layer 140a may be an undoped gallium nitride; the channel-supplying layer 150a may be an undoped aluminum gallium nitride layer; and the upper channel layer 160 may be an undoped gallium nitride layer. Each of the lower channel layer 140a, the channel-supplying layer 150a, and the upper channel layer 160a may be formed to have the same polarity as that of the high-resistance semiconductor layer 132 that is formed therebeneath. For example, a part of the lower channel layer 140a, a part of the channel-supplying layer 150a, and a part of the upper channel layer 160a that vertically faces the face-inversion layer 120 may have a Ga-face polarity; and a part of the lower channel layer 140a, a part of the channel-supplying layer 150a, and a part of the upper channel layer 160a that do not vertically face the face-inversion layer 120 may have an N-face polarity.

The source and drain electrodes 182 and 184 may be formed to pass through the gate insulation layer 172, the first passivation layer 174, and the second passivation layer 176 that are sequentially formed on the upper channel layer 160a and to be connected to the upper channel layer 160a. The gate electrode 186 may pass through the first and second passivation layers 174 and 176 between the source and drain electrodes 182 and 184 and be formed on the upper channel layer 160a. The gate insulation layer 172 may be interposed between the gate electrode 186 and the upper channel layer 160a.

The HEMT device 100a may form a hetero-structure in which the lower channel layer 140a, the channel-supplying layer 150a, and the upper channel layer 160a are GaN/AlGaN/GaN layers. A 2DEG region may be formed in the lower channel layer 140a at a region facing the gate electrode 186, i.e., at a part under the gate electrode 186; and the 2DEG region may be formed in the upper channel layer 160a at a region not facing the gate electrode 186.

When a voltage is applied to the gate electrode 186, currents flow through the 2DEG region in the upper channel layer 160a between the source electrode 182 and the drain electrode 184 and thus the upper channel layer 160a may work as a channel region. The 2DEG region in the upper channel layer 160a is discontinuous at a part under the gate electrode 186, and thus, the HEMT device 100a may exhibit a stable, normally Off characteristic.

FIG. 5 is a cross-sectional view of an HEMT device 100b according to an exemplary embodiment of the present inventive concepts. The HEMT device is similar to the HEMT device 100 described with reference to FIG. 1 except for an arrangement of a face-inversion layer 120b that may be formed on a part of the buffer layer 115b that does not face the gate electrode.

A high-resistance semiconductor layer 134 may be formed on the buffer layer 115b and on the face-inversion layer 120b, and the first region 134a of the high-resistance semiconductor layer 134 that faces the gate electrode 186 may be grown using the buffer layer 115b as a seed layer. Thus, the high-resistance semiconductor layer 134 may have a crystal direction with the same polarity as that of the buffer layer 115b.

In exemplary embodiments, the buffer layer 115b may be formed to have an N-face polarity; and the first region 134a of the high-resistance semiconductor layer 134 is also formed to have an N-face polarity. The second region 134b of the high-resistance semiconductor layer 134 under which the face-inversion layer 120b is formed may have a Ga-face polarity.

According to embodiments of the present inventive concepts, only the part of the channel layer 140b under the gate electrode 186 may be formed to have a polarity different from that of a part of the channel layer 140b that does not face the gate electrode 186. Accordingly, a 2DEG region may not be formed at the part of the channel layer 140b facing the gate electrode 186. Thus, the HEMT device 100b may exhibit a stable, normally Off characteristic.

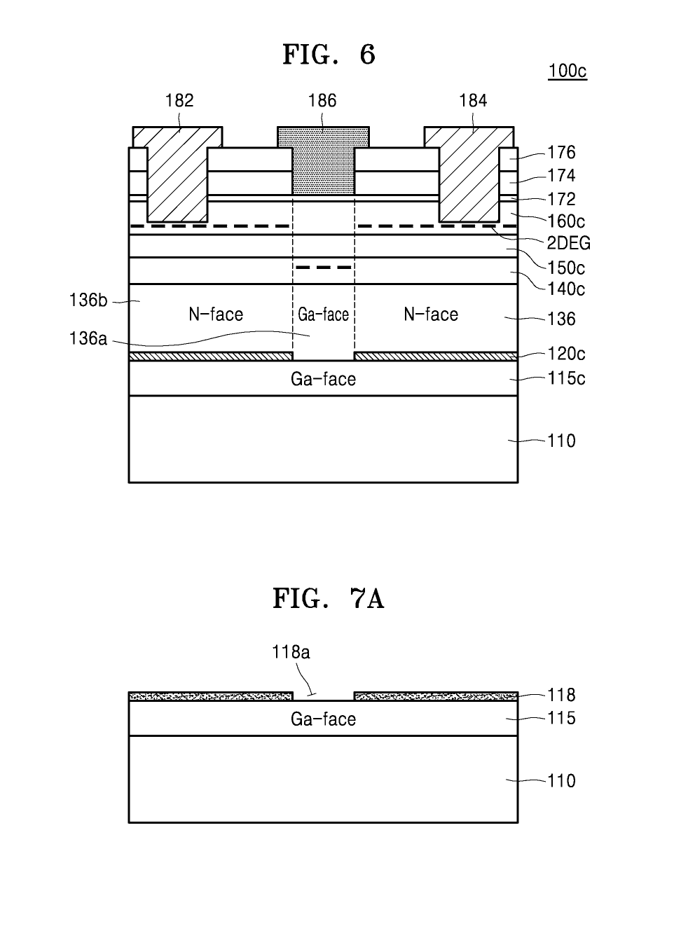

FIG. 6 is a cross-sectional view of an HEMT device 100c according to an exemplary embodiment of the present inventive concepts. The HEMT device is similar to the HEMT device 100 described with reference to FIG. 1 except for an arrangement of a face-inversion layer 120c that may be formed on a part of the buffer layer 115c that does not face the gate electrode 186.

A high-resistance semiconductor layer 136 may be formed on the buffer layer 115c and on the face-inversion layer 120c, and a first region 136a of the high-resistance semiconductor layer 136 that faces the gate electrode 186 may be grown using the buffer layer 115c as a seed layer. Thus, the high-resistance semiconductor layer 136 may have a crystal direction with the same polarity as that of the buffer layer 115c.

In exemplary embodiments, the buffer layer 115c may be formed to have a Ga-face polarity, and the first region 136a of the high-resistance semiconductor layer 136 may be also formed to have a Ga-face polarity. A second region 136b of the high-resistance semiconductor layer 136 under which the face-inversion layer 120c is formed may also have a Ga-face polarity.

According to embodiments of the present inventive concepts, only the part of the channel layer 140c under the gate electrode 186 may be formed to have a polarity different from that of a part of the channel layer 140c that does not face the gate electrode 186. Accordingly, a 2DEG region may be formed at the part of an upper channel layer 160c not facing the gate electrode 186 and at the part of the lower channel layer 140c facing the gate electrode 186. Thus, the upper channel layer 160c working as a channel region of the HEMT device 100c may include a 2DEG region that is discontinuous at a part facing the gate electrode 186, and the HEMT device 100c may exhibit a stable, normally Off characteristic.

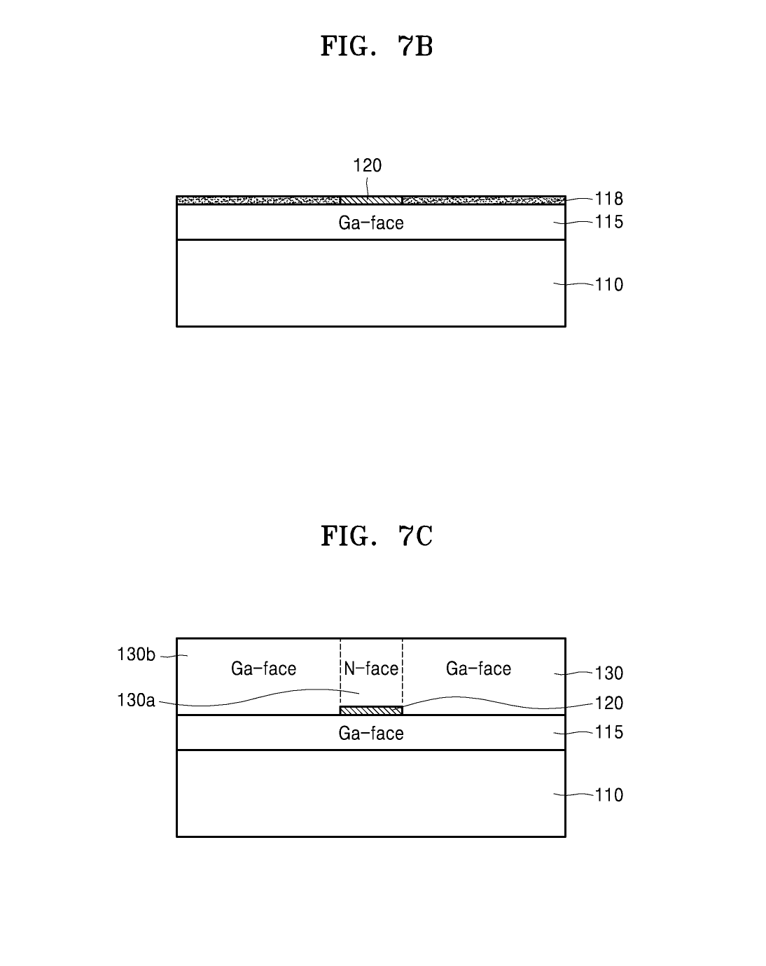

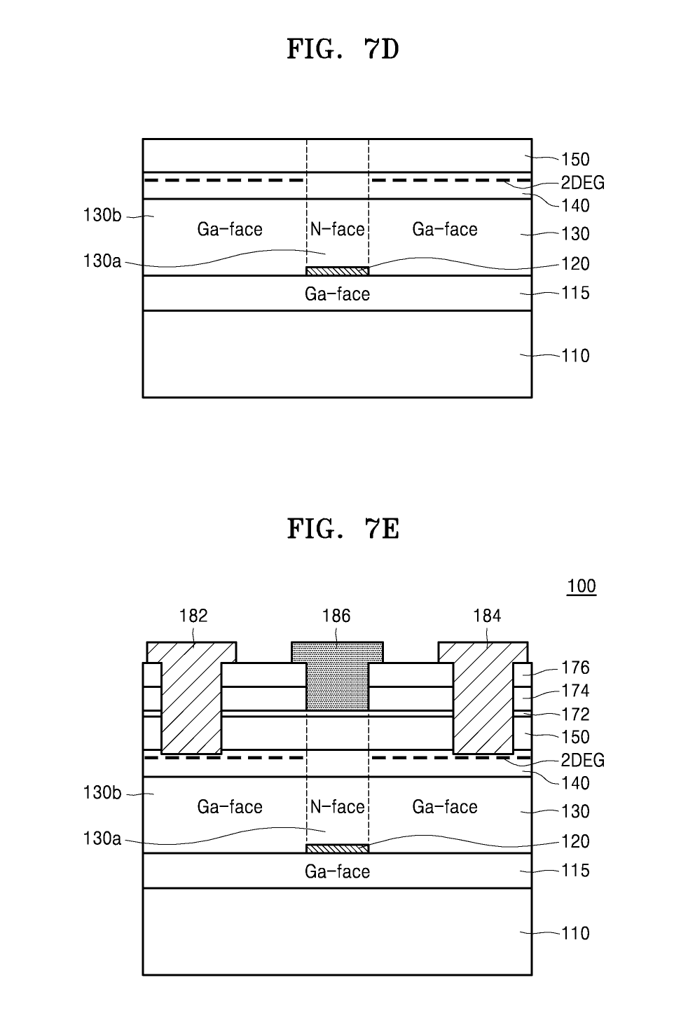

FIGS. 7A to 7E are cross-sectional views illustrating a method of fabricating an HEMT device according to an exemplary embodiment of the present inventive concepts. The method may be related to fabricating the HEMT device described with reference to FIG. 1.

Referring to FIG. 7A, the buffer layer 115 may be formed on the substrate 110. In exemplary embodiments, the buffer layer 115 may include gallium nitride and may be formed to have a Ga-face polarity. The material of the buffer layer 115 is not limited thereto and may include, e.g., at least one of the following compositions: aluminum nitride, aluminum gallium nitride, silicon carbon nitride, etc. In exemplary embodiments, the buffer layer 115 may be formed on the substrate by a molecular beam epitaxy (MBE) process, a hydride vapor phase epitaxy (HVPE) process, or a metal-organic vapor phase epitaxy (MOVPE) process.

In an exemplary process to form the buffer layer 115, a nitrogen source may be first provided to the surface of the substrate 110, and then a gallium source may be provided so that a gallium nitride layer may be epitaxially-grown. In such a case, the gallium nitride layer in which nitrogen, gallium, nitrogen, and gallium are stacked sequentially along a vertical direction from the surface of the substrate 110 may be formed; and gallium atoms may be disposed on an exposed surface of the formed gallium nitride layer. As shown in (B) of FIG. 2 with respect to a crystal structure of gallium nitride, the gallium nitride layer may grow in the [0001] direction of a wurtzite crystal structure so that nitrogen atoms are disposed directly on gallium atoms. In exemplary embodiments, the gallium source may include trimethylgallium (TMGa) or triethylgallium (TEGa); and the nitrogen source may include ammonia (NH₃). In addition, a source gas to form the buffer layer 115 may include trimethylaluminum (TMAl), trimethylindium (TMIn), or bis-cyclopentadienyl magnesium (Cp₂Mg).

Subsequently, a mask layer 118 may be formed on the buffer layer 115. The mask layer 118 may include an opening 118a through which a region of the buffer layer 115 may be exposed. For example, the mask layer 118 may include silicon oxide or silicon nitride, but the material of the mask layer 118 is not limited thereto.

Referring to FIG. 7B, a face-inversion layer 120 may be formed on the surface of the buffer layer 115 exposed through the opening 118a of the mask layer 118. In exemplary embodiments, the face-inversion layer 120 may include at least one of the following compositions: magnesium-doped gallium nitride, aluminum nitride doped with p-type impurities, magnesium carbide, magnesium carbon nitride, etc. In addition, the face-inversion layer 120 may be formed by an MBE process, an HYPE process, or an MOVPE process. In an exemplary process to form the face-inversion 120, the face-inversion layer 120 may be formed by forming an undoped gallium nitride layer and then implanting a dopant, such as magnesium, aluminum, carbon, zinc, indium, etc., into the gallium nitride layer.

Unlike FIG. 7B, where the mask layer 118 is disposed on a portion of the buffer layer 115 on which a gate electrode 186 (see FIG. 7E) will be formed in a subsequent process, a face-inversion layer 120c (See FIG. 6) may not overlap with the gate electrode 186. In such a case, the HEMT device 100c, as shown in FIG. 6, may be formed.

Referring to FIG. 7C, the mask layer 118 (See FIG. 7B) may be removed. In this case, the surface of the buffer layer 115 that has been covered by the mask layer 118 may be exposed again. For example, the mask layer 118 may be removed by a dry or wet etching process using an etchant that selectively etches only the mask layer 118.

Subsequently, a high-resistance semiconductor layer 130 may be formed on the buffer layer 115 and on the face-inversion layer 120. The high-resistance semiconductor layer 130 may include gallium nitride. In an exemplary process to form the high-resistance semiconductor layer 130, a gallium nitride layer may be formed; and, subsequently, dopants, such as any of magnesium, zinc, carbon, steel, etc., may be implanted into the gallium nitride layer. Alternatively, the dopants may be in-situ doped in the process of forming the gallium nitride layer. In exemplary embodiments, the gallium nitride layer may be grown at a low temperature, e.g., at about 500° C. to 600° C. Thus, the high-resistance semiconductor layer 130 may have a sheet resistance in a range of about 10⁷ Ωcm² to about 10¹¹ Ωcm².

In this case, a first region 130a of the high-resistance semiconductor layer 130 on the face-inversion layer 120 may be grown to have a polarity that is different from that of the buffer layer 115, i.e., to have an N-face polarity. A second region 130b of the high-resistance semiconductor layer 130 on the buffer layer 115 may be grown to have the same polarity as that of the buffer layer 115, i.e., to have a Ga-face polarity. This is because the face-inversion layer 120 may change a crystal direction of the gallium nitride layer from the [0001] direction to the [000 1̅] direction.

The buffer layer 115 and the face-inversion layer 120 may work as templates for growing a gallium nitride layer having an N-face polarity and a gallium nitride layer having a Ga-face polarity, respectively. Thus, the first and second regions 130a and 130b of the high-resistance semiconductor layer 130 having different polarities from each other may be formed simultaneously in a single process using the face-inversion layer as the template.

Referring to FIG. 7D, a channel layer 140 may be formed on the high-resistance semiconductor layer 130. The channel layer 140 may include at least one of various materials including aluminum nitride, gallium nitride, indium nitride, indium gallium nitride, aluminum gallium nitride, aluminum indium nitride, etc. For example, the channel layer 140 may include an undoped gallium nitride layer and may be formed with a thickness in a range of about 10 nm to about 100 nm.

Subsequently, a channel-supplying layer 150 may be formed on the channel layer 140. The channel-supplying layer 150 may include a semiconductor material having a band gap energy higher than that of the channel layer 140. The channel-supplying layer 150 may have a single layer or a multi-layered structure that includes one or more materials selected from nitrides including at least one of aluminum, gallium, and indium. For example, the channel-supplying layer 150 may include undoped aluminium gallium nitride and have a thickness of about 20 nm to about 50 nm.

As a hetero-structure between the channel layer 140 and the channel-supplying layer 150 is formed, it is possible to form a 2DEG region in the channel layer 140 having a Ga-face polarity. Since the channel layer 140 and the channel-supplying layer 150 on the first region 130a of the high-resistance semiconductor layer 130 are arranged to have an N-face polarity, the 2DEG region is not formed in the channel layer 140. Thus, since the 2DEG region is not formed at the part of the channel layer 140 facing the first region 130a, a discontinuous section of a 2DEG region may be formed in the channel layer 140.

Unlike FIG. 7D, the buffer layer 115 may be formed to have an N-face polarity. For example, when a gallium source is first provided onto a substrate 110 and then a nitrogen source is provided so that a gallium nitride layer is epitaxially grown, the gallium nitride layer in which gallium, nitrogen, gallium, and nitrogen are sequentially stacked upwardly from the surface of the substrate 110 may be formed, and nitrogen atoms may be disposed on an exposed surface of the formed gallium nitride layer. Since a face-inversion layer 120 is formed on the buffer layer 115, each of the first region 130a of the high-resistance semiconductor layer 130, a part of the channel layer 140, and a part of the channel-supplying layer 150 may be formed to have a Ga-face polarity. In this case, it is possible to further form an upper channel layer 160a (See FIG. 4) on the channel-supplying layer; and the upper channel layer 160a may include, for example, undoped gallium nitride. Accordingly, the HEMT device 100a according to FIG. 4 may be formed where a 2DEG region is formed in the upper channel layer 160a.

Referring to FIG. 7E, a gate insulation layer 172, a first passivation layer 174, and a second passivation layer 176 may be sequentially formed on the channel-supplying layer 150. The gate insulation layer 172 may include a dielectric material, such as silicon oxide, silicon nitride, aluminium oxide, tantalum oxide, hafnium oxide, etc. In addition, the first passivation layer 174 and the second passivation layer 176 may include silicon oxide, silicon nitride, silicon oxynitride, etc.

Subsequently, the second passivation layer 176, the first passivation layer 174, the gate insulation layer 172, and the channel-supplying layer 15 are sequentially etched to form first trenches (not shown) exposing a top surface of the channel layer 140. Then, the first trenches may be filled with a conductive material (not shown) to form a source electrode 182 and a drain electrode 184 in the first trenches. For example, the first trenched may be formed by an etching process, such as an inductively coupled plasma reactive ion etching (ICP-RIE) process.

Subsequently, heat treatment may further be performed at a temperature of about 500° C. to 550° C.

A part of the second passivation layer 176 and a part of the first passivation layer 174 between the source electrode 182 and the drain electrode 184 are sequentially etched to form a second trench (not shown) through which the top of the gate insulation layer 172 is exposed, and the second trench may be filled with a conductive material to form the gate electrode 186 in the second trench. Thus, the gate electrode 186 may be disposed on the channel-supplying layer 150, and the gate insulation layer 172 may be interposed between the gate electrode 186 and the channel-supplying layer 150. The gate electrode 186 may be formed to be disposed on the first region 130a of the high-resistance semiconductor layer 130 under which the face-inversion layer 120 is formed.

According to embodiments of the present inventive concepts, a 2DEG region may not be formed in a portion of the channel layer 140 under which the face-inversion layer is disposed. Thus, even if the part of the channel-supplying layer under the gate electrode 186 is not etched, it is possible to implement a normally Off characteristic. Thus, non-uniform thickness distribution of the channel-supplying layer, which may occur when directly etching the part of the channel-supplying layer under the gate electrode, may be avoided. Also, fluctuations in on-resistance and fluctuations in threshold voltage of the HEMT device due to the non-uniform thickness distribution may be avoided.

Thus, the HEMT device 100 is completed through the above-described processes.

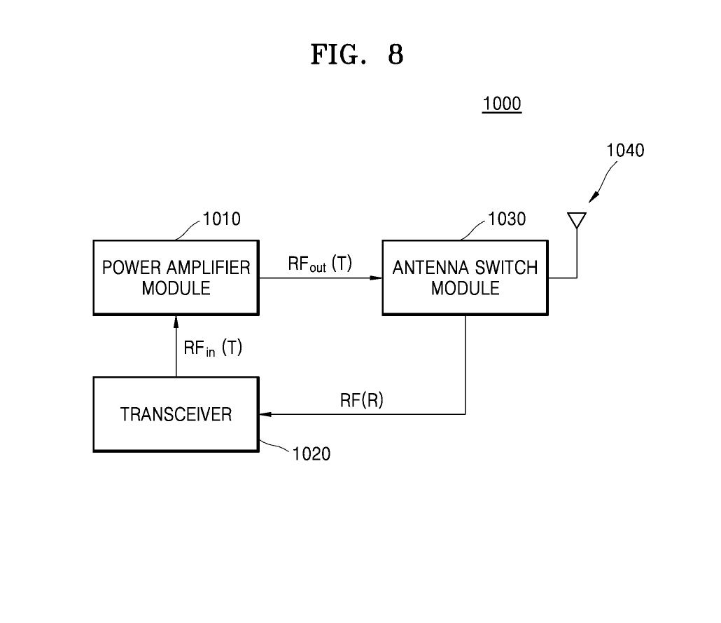

FIG. 8 is a schematic block diagram of a power module system 1000 employing a high electron mobility transistor according to an exemplary embodiment.

Referring to FIG. 8, the system 1000 may include a power amplifier module 1010 that includes HEMT devices 100 and 100a to 100d according to exemplary embodiments of the present inventive concepts. In addition, the power amplifier module 1010 may be a radio frequency (RF) power amplifier module. Such a system 1000 may include a transceiver 1020 that is coupled to the RF power amplifier module 1010.

The RF power amplifier module 1010 may receive an RF input signal, RFᵢₙ(T), from the transceiver 1020 and may amplify the RF input signal, RFᵢₙ(T), to provide an RF output signal, RFₒᵤₜ(T). The RF input signal, RFᵢₙ(T), and the RF output signal, RFₒᵤₜ(T), may correspond to the transmitting mode of signals indicated by arrows in FIG. 8.

The amplified RF output signal, RFₒᵤₜ(T), may be provided to an antenna switch module (ASM) 1030, and facilitate the over the air (OTA) transmission of the RF output signal, RFₒᵤₜ(T), through an antenna structure 1040. The antenna switch module 1030 may also receive RF signals, RF(R), through the antenna structure and couple the received RF signals, RF(R), to a transceiver; and these may correspond to the receiving mode of signals.

In exemplary embodiments, the antenna structure 1040 may include unidirectional or multi-directional and/or omni-directional antennas. For example, the antenna structure 1040 may be a dipole, monopole, patch, loop, or micro strip antenna. In addition, the antenna structure 1040 is not limited thereto but may include all kinds of antennas that are suitable for the OTA transmission or reception of RF signals.

The system 1000 may include a power amplification function. For example, the system 1000 may be used for power amplification at a high frequency and for various purposes such as a personal communication service, satellite communication, a radar system, broadcasting communication, and medical equipment.

While the present inventive concepts have been particularly shown and described with reference to exemplary embodiments thereof, it will be understood by those of ordinary skill in the art that various changes in form and details may be made therein without departing from the spirit and scope of the present inventive concepts, as defined by the following claims.

What is claimed is:

1. A high electron mobility transistor (HEMT) device, comprising:
a substrate;
a buffer layer on the substrate;
a face-inversion layer on a part of the buffer layer;
a plurality of semiconductor layers on the face-inversion layer and on the buffer layer; and
a source electrode, a drain electrode, and a gate electrode on the plurality of semiconductor layers.

2. The HEMT device of claim 1, wherein a polarity of the buffer layer is different from polarities of the plurality of semiconductor layers that are arranged on the face-inversion layer.

3. The HEMT device of claim 1, further comprising:
a channel region formed in the plurality of semiconductor layers; and
a two-dimensional electron gas (2DEG) region formed in the channel region, wherein the 2DEG region is not formed on a part of the channel region that overlaps with the gate electrode.

4. The HEMT device of claim 1, wherein the face-inversion layer is disposed to overlap with the gate electrode.

5. The HEMT device of claim 4, wherein the buffer layer has a Ga-face polarity, parts of the plurality of semiconductor layers on the buffer layer have the Ga-face polarity, and parts of the plurality of semiconductor layers on the face-inversion layer have an N-face polarity.

6. The HEMT device of claim 5, wherein the plurality of semiconductor layers comprise:
a first semiconductor layer on the buffer layer and on the face-inversion layer, wherein the first semiconductor layer includes gallium nitride (GaN), and wherein a channel region is formed in the first semiconductor layer; and
a second semiconductor layer on the first semiconductor layer, wherein the second semiconductor layer includes aluminum gallium nitride (AlₓGa₁₋ₓN), where 0<x<1.

7. The HEMT device of claim 4, wherein the buffer layer has an N-face polarity, parts of the plurality of semiconductor layers on the buffer layer have the N-face polarity, and parts of the plurality of semiconductor layers on the face-inversion layer have a Ga-face polarity.

8. The HEMT device of claim 7, wherein the plurality of semiconductor layers comprise:
a first semiconductor layer on the buffer layer and on the face-inversion layer, wherein the first semiconductor layer includes gallium nitride (GaN), and wherein a channel region is formed in the first semiconductor layer;
a second semiconductor layer on the first semiconductor, wherein the second semiconductor layer includes aluminum gallium nitride (AlₓGa₁₋ₓN), where 0<x<1; and
a third semiconductor layer on the second semiconductor layer, wherein the third semiconductor layer includes gallium nitride (GaN).

9. The HEMT device of claim 1, wherein the face-inversion layer is disposed not to overlap with the gate electrode.

10. The HEMT device of claim 9, wherein the face-inversion layer is formed to overlap with the source electrode and the drain electrode.

11. The HEMT device of claim 1, wherein the face-inversion layer comprises a composition selected from magnesium-doped gallium nitride, aluminum nitride doped with p-type impurities, magnesium carbide (MgC), and magnesium carbon nitride (MgCN).

12. The HEMT device of claim 1, further comprising a high-resistance semiconductor layer under the plurality of semiconductor layers.

13. A high electron mobility transistor (HEMT), comprising:
a substrate a buffer layer on the substrate;
a face-inversion layer on a part of the buffer layer;
a high-resistance semiconductor layer on the buffer layer and on the face-inversion layer;
a channel layer and a channel-supplying layer sequentially formed on the high-resistance semiconductor layer;
a source electrode and a drain electrode connected to the channel layer; and
a gate electrode on the channel-supplying layer,
wherein a polarity of a part of the buffer layer under the face-inversion layer is different from a polarity of a part of the high-resistance semiconductor layer on the face-inversion layer.

14. The HEMT of claim 13, wherein a bottom of the gate electrode, nearest the substrate, is on a level more remote from the substrate than is a top of the channel-supplying layer, most remote from the substrate.

15. The HEMT of claim 13, wherein a part of the channel-supplying layer under the gate electrode has a flat shape.

16. A radio frequency power amplifier module, comprising:
a power amplifier module including at least one high electron mobility transistor (HEMT), including:
a substrate;
a buffer layer on the substrate;
a face-inversion layer on a part of the buffer layer;
a plurality of semiconductor layers on the face-inversion layer and on the buffer layer; and
a source electrode, a drain electrode, and a gate electrode on the plurality of semiconductor layers;
a transceiver coupled with the power amplifier module and configured to receive an input signal and to transmit the input signal to the power amplifier module, wherein the power amplifier module is configured to amplify the input signal received from the transceiver; and
an antenna switch module coupled with the power amplifier module and including an antenna structure, wherein the antenna switch module is configured to receive the amplified input signal from the power amplifier module and to transmit the amplified input signal over the air via the antenna structure.

17. The radio frequency power amplifier module of claim 16, wherein the antenna switch module is also configured to receive the input signal through the antenna structure and to transmit the input signal to the transceiver.

18. The radio frequency power amplifier module of claim 16, wherein a polarity of the buffer layer is different from polarities of the plurality of semiconductor layers that are arranged on the face-inversion layer.

19. The radio frequency power amplifier module of claim 16, further comprising:
a channel region formed in the plurality of semiconductor layers; and
a two-dimensional electron gas (2DEG) region formed in the channel region, wherein the 2DEG region is not formed on a part of the channel region that overlaps with the gate electrode.

20. The radio frequency power amplifier module of claim 16, wherein the face-inversion layer is disposed to overlap either (a) with the gate electrode but not with the source electrode and not with the drain electrode or (b) with the source electrode and with the drain electrode but not with the gate electrode.
